(19) United States
(12) Patent Application Publication
(10) Pub. No.: US 2021/0210721 A1
(43) Pub. Date: Jul. 8, 2021

(54) METHOD FOR PACKAGING DISPLAY SUBSTRATE AND PACKAGING STRUCTURE

(71) Applicant: BOE TECHNOLOGY GROUP CO., LTD., Beijing (CN)

(72) Inventors: Jinxiang XUE, Beijing (CN); Chengyuan LUO, Beijing (CN); Zhongyuan SUN, Beijing (CN)

(21) Appl. No.: 16/768,060

(22) PCT Filed: Dec. 16, 2019
(86) PCT No.: PCT/CN2019/125622

§ 371 Date: May 28, 2020

(30) Foreign Application Priority Data
Jan. 23, 2019 (CN) 201910063640.X

(51) Int. Cl. H01L 51/52; H01L 51/56

(52) U.S. Cl. CPC H01L 51/5253; H01L 2251/5369; H01L 51/5256; H01L 51/56

(57) ABSTRACT

The present disclosure relates to a method for packaging a display substrate and a packaging structure. The packaging method includes: preparing a light conversion structure in a non-display region of the base substrate capable of converting the received first light into second light; preparing one or more organic packaging layers on a surface of the base substrate on which the light conversion structure is formed; irradiating the light conversion structure with the first light so that the rheological organic material layer in a region in which the light conversion structure is located is cured with the converted second light; and then curing all of the rheological organic material layer, in which the light conversion structure is arranged on a surface of the corresponding organic packaging layer close to the base substrate.

### CROSS-REFERENCE TO RELATED APPLICATION

This application claims a priority to Chinese Patent Application No. 201910063640.X filed on Jan. 23, 2019, the disclosures of which are incorporated in their entirety by reference herein.

### TECHNICAL FIELD

The present disclosure relates to the technical field of packaging an electronic product, and in particular to a method of for packaging a display substrate and a packaging structure prepared by the method.

### BACKGROUND

An organic light emitting diode (OLED) display device is applied to various fields due to its advantages, such as self-illumination, flexibility, high contrast and low power consumption. However, since the OLED display device is easily corroded by water and oxygen, studies on how to avoid the erosion of water and oxygen and increase the service life of the OLED display device have attracted widespread attention.

In order to prevent the OLED display device from being corroded by water and oxygen, the OLED display device is generally subjected to a thin-film packaging, that is, both an organic packaging layer and an inorganic packaging layer are stacked on the surface of the OLED display device. The inorganic packaging layer mainly plays a role of blocking water and oxygen, and the organic packaging layer mainly plays a role of releasing stress and planarization. However, during the preparing an organic packaging layer, the rheological organic material for preparing the organic packaging layer often go beyond the coverage of the inorganic packaging layer. The organic packaging layer has a weak blocking effect to water and oxygen, and can easily become a path for water and oxygen to invade. This leads to a reduction in the reliability of packaging the display device.

### SUMMARY

In an aspect, the present disclosure provides a method for packaging a display substrate, including: providing a base substrate, the base substrate including a display region and a non-display region surrounding the display region; preparing a light conversion structure in the non-display region of the base substrate, the light conversion structure including a light conversion material capable of converting received first light into second light; and preparing one or more organic packaging layers and one or more inorganic packaging layers on a surface of the base substrate on which the light conversion structure is formed, to form a composite packaging layer in which the inorganic packaging layers and the organic packaging layers are alternately stacked; in which the preparing the one or more organic packaging layers includes: forming a rheological organic material layer, and irradiating the light conversion structure with the first light, so that the rheological organic material layer in a region in which the light conversion structure is located is cured with the second light converted from the first light by the light conversion structure; and curing all of the rheological organic material layer to form the one or more organic packaging layers, in which an orthogonal projection of the organic packaging layer on the base substrate is surrounded by an orthogonal projection of the light conversion structure on the base substrate.

Optionally, the preparing the light conversion structure in the non-display region of the base substrate includes: preparing at least two retaining wall patterns in the non-display region of the base substrate, each of the at least two retaining wall patterns surrounding the display region, heights of the at least two retaining wall patterns in a direction perpendicular to the base substrate gradually increasing along a direction away from the display region, and a groove is formed between adjacent retaining wall patterns; and preparing a light conversion pattern in the groove, the light conversion pattern including a light conversion material capable of converting the received first light into the second light.

Optionally, the preparing the one or more organic packaging layers includes: preparing organic packaging layers corresponding to the grooves respectively, and during the forming the rheological organic material layer corresponding to the organic packaging layer, the light conversion pattern in a target groove corresponding to the organic packaging layer is irradiated with the first light, so that the rheological organic material layer in a region in which the target groove is located is cured with the second light converted from the first light by the light conversion pattern, and in a direction perpendicular to the base substrate, the rheological organic material layer in a region in which the target groove is located is lower than the retaining wall pattern away from the display region among the retaining wall pattern for forming the target groove.

Optionally, the preparing the one or more inorganic packaging layers includes preparing a plurality of inorganic packaging layers, in which an orthogonal projection of the light conversion structure on the base substrate is located within an orthogonal projection of any one of the plurality of inorganic packaging layers on the base substrate, the inorganic packaging layers and the organic packaging layers are alternately stacked, and an outermost layer located on an outer surface of the composite packaging layer is the inorganic packaging layer.

Optionally, the method includes: preparing a first retaining wall pattern and a second retaining wall pattern in the non-display region of the base substrate, in which the first retaining wall pattern is located between the display region and the second retaining wall pattern, and a first groove is formed between the first retaining wall pattern and the second retaining wall pattern; preparing a first light conversion pattern in the first groove; preparing a first inorganic packaging layer; preparing a first organic packaging layer, which includes forming a first rheological organic material layer on a surface of the first inorganic packaging layer away from the base substrate, irradiating the first light conversion pattern with the first light, so that the first rheological organic material layer in a region in which the first groove is located is cured with the second light converted from the first light by the first light conversion pattern, and in a direction perpendicular to the base substrate, the first rheological organic material layer in a region in which the first groove is located is lower than the second retaining wall pattern, and curing all of the first rheological organic material layer; and preparing a second inorganic packaging layer on a surface of the first organic packaging layer away from the base substrate.

Optionally, the at least two retaining wall patterns includes a first retaining wall pattern, a second retaining wall pattern, and a third retaining wall pattern; a first groove is formed between the first retaining wall pattern and the second retaining wall pattern, and a second groove is formed between the second retaining wall pattern and the third retaining wall pattern; and the composite packaging layer includes two organic packaging layers and three inorganic packaging layers.

Optionally, the base substrate is a light transmitting substrate, and layers between the base substrate and the light conversion structure are all light transmitting film layers.

Optionally, the irradiating the light conversion structure with the first light includes irradiating the light conversion structure with the first light from a side of the base substrate, and after the light conversion structure has converted the first light into the second light, the second light directly irradiates the rheological organic material layer in a region in which the light conversion structure is located.

Optionally, a layer having light reflecting effect is arranged between the base substrate and the light conversion structure.

Optionally, the irradiating the light conversion structure with the first light specifically includes: irradiating the light conversion structure with the first light from a side of the light conversion structure away from the base substrate, and after the light conversion structure has converted the first light into the second light, the second light is reflected by the layer having light reflecting effect, to irradiate the rheological organic material layer in a region in which the light conversion structure is located.

Optionally, the first light includes an infrared light, and the second light includes an ultraviolet light.

Optionally, the preparing the at least two retaining wall patterns in the non-display region of the base substrate includes: preparing an ultraviolet blocking material; forming a blocking film by depositing the ultraviolet light blocking material, the blocking film at least covering a non-display region of the base substrate; and patterning the blocking film to obtain the at least two retaining wall patterns.

In another aspect, the present disclosure provides a packaging structure for a display substrate, including: a base substrate, the base substrate including a display region and a non-display region surrounding the display region; a light conversion structure arranged in the non-display region, in which the light conversion structure includes a light conversion material capable of converting the received first light into the second light having a curing effect on organic materials; a composite packaging layer arranged on a surface of the base substrate on which the light conversion structure is formed, in which the composite packaging layer includes one or more organic packaging layers and one or more inorganic packaging layers that are alternately stacked, an orthogonal projection of the organic packaging layer on the base substrate partially overlaps an orthogonal projection of the light conversion structure on the base substrate, and the orthogonal projection of the organic packaging layer on the base substrate is surrounded by the orthogonal projection of the light conversion structure on the base substrate.

Optionally, the light conversion structure includes: at least two retaining wall patterns, in which each of the at least two retaining wall patterns surrounds the display region, heights of the at least two retaining wall patterns in a direction perpendicular to the base substrate gradually increase along a direction away from the display region, and a groove is formed between adjacent retaining wall patterns; and a light conversion pattern arranged in the groove, the light conversion pattern including a light conversion material capable of converting the received first light into the second light.

Optionally, the organic packaging layers correspond to the grooves respectively, and in a direction perpendicular to the base substrate, a portion of each organic packaging layer in a region in which a target groove is located is lower than the retaining wall pattern away from the display region among the retaining wall pattern for forming the target groove, and the target grooves correspond to the organic packaging layers respectively.

Optionally, the composite packaging layer includes a plurality of inorganic packaging layers, an orthogonal projection of the light conversion structure on the base substrate is located within an orthogonal projection of the plurality of inorganic packaging layers on the base substrate, the inorganic packaging layers and the organic packaging layers are alternately stacked, and an outermost located on an outer surface of the composite packaging layer is the inorganic packaging layer.

Optionally, the at least two retaining wall patterns include a first retaining wall pattern and a second retaining wall pattern, in which the first retaining wall pattern is located between the display region and the second retaining wall pattern, and a first groove is formed between the first retaining wall pattern and the second retaining wall pattern; the light conversion pattern includes a first light conversion pattern arranged in the first groove; the composite packaging layer includes: a first inorganic packaging layer arranged on a side of the first light conversion pattern away from the base substrate; a first organic packaging layer arranged on a side of the first inorganic packaging layer away from the base substrate, in which in a direction perpendicular to the base substrate, a portion of the first organic packaging layer in a region where the first groove is located is lower than the second retaining wall pattern; and a second inorganic packaging layer arranged on a surface of the first organic packaging layer away from the base substrate.

Optionally, the first light includes infrared light, the second light includes ultraviolet light, and the at least two retaining wall patterns are made of an ultraviolet blocking material.

Optionally, the light conversion pattern is made of a compound doped with rare earth ions, and the compound material includes one or more of oxides, fluorides, oxyfluorides, sulfides and halides.

Optionally, the at least two retaining wall patterns includes a first retaining wall pattern, a second retaining wall pattern, and a third retaining wall pattern; a first groove is formed between the first retaining wall pattern and the second retaining wall pattern, and a second groove is formed between the second retaining wall pattern and the third retaining wall pattern; and the composite packaging layer includes two organic packaging layers and three inorganic packaging layers.

### BRIEF DESCRIPTION OF THE DRAWINGS

FIG. 1 is a schematic view showing a packaging structure according to an embodiment of the present disclosure;

FIG. 2 is a schematic view showing irradiating a light conversion pattern with the first light in a method according to an embodiment of the present disclosure;

FIG. 3 is a schematic view showing irradiating a light conversion pattern with first light in a method according to another embodiment of the present disclosure;

FIG. 4 is a schematic view showing a packaging structure according to another embodiment of the present disclosure.

### DETAILED DESCRIPTION

In order to make the technical problems to be solved, the technical solutions, and the advantages of the embodiments of the present disclosure, the present disclosure will be described hereinafter in conjunction with the drawings and specific examples.

According to an embodiment of the present disclosure, a method for packaging a display substrate is provided, including: providing a base substrate, the base substrate including a display region and a non-display region surrounding the display region; preparing a light conversion structure in the non-display region of the base substrate, the light conversion structure including a light conversion material capable of converting the received first light into second light; and preparing one or more organic packaging layers and one or more inorganic packaging layers on a surface of the base substrate on which the light conversion structure is formed, to form a composite packaging layer in which the inorganic packaging layers and the organic packaging layers are alternately stacked; in which the preparing the one or more organic packaging layers includes: forming a rheological organic material layer, and irradiating the light conversion structure with the first light, so that the rheological organic material layer in a region in which the light conversion structure is located is cured with the second light converted from the first light by the light conversion structure; and curing all of the rheological organic material layer to form the one or more organic packaging layers, in which an orthogonal projection of the organic packaging layer on the base substrate is surrounded by an orthogonal projection of the light conversion structure on the base substrate.

In the above solution according to an embodiment of the present disclosure, a non-display region of the base substrate is prepared to convert the first light into the second light having a curing effect on the organic material. During the preparing the organic packaging layers in the composite packaging layer, a rheological organic material layer is first formed on the base substrate, and then the light conversion structure is irradiated with the first light, so that the rheological organic material layer in a region in which the light conversion structure is located is irradiated and cured with the second light converted from the first light by the light conversion structure. This enables the rheological organic material layer to be confined within the region defined by the light conversion structure, to prevent the rheological organic material layer from continuing extending toward the edge of the base substrate. In view of this, the above technical solutions provided by the embodiments of the present disclosure can produce the following beneficial technical effects: by curing the rheological organic material layer in the region in which the light conversion structure is located, the rheological organic material layer is confined within the region defined by the light conversion structure, to prevent the rheological organic material layer from extending toward the edge of the base substrate; thus, the inorganic packaging layer can completely cover the organic packaging layer, thereby avoiding the organic packaging layer to be exposed to water and oxygen in the air, and effectively improving the reliability of packaging the display substrate.

Specifically referring to FIG. 1, an embodiment of the present disclosure provides a method for packaging a display substrate, including: providing a base substrate 10, the base substrate 10 including a display region and a non-display region surrounding the display region; preparing a light conversion structure 2 in the non-display region of the base substrate 10, the light conversion structure 2 including a light conversion material capable of converting the received first light into the second light; preparing a composite packaging layer on a surface of the base substrate 10 on which the light conversion structure 2 is formed, in which the composite packaging layer includes one or more organic packaging layers 3 and one or more inorganic packaging layers 4 that are alternately stacked; in which the preparing the one or more organic packaging layers 3 includes: forming a rheological organic material layer, and irradiating the light conversion structure 2 with the first light, so that the rheological organic material layer in a region in which the light conversion structure 2 is located is cured with the second light converted from the first light by the light conversion structure 2; and then curing all of the rheological organic material layer to form the one or more organic packaging layers 3, in which an orthogonal projection of the organic packaging layer 3 on the base substrate 10 is surrounded by an orthogonal projection of the light conversion structure 2 on the base substrate 10.

Specifically, the base substrate 10 may be a transparent substrate 10 or an opaque substrate 10. For example, the base substrate 10 is a glass substrate. The base substrate 10 includes a display region and a non-display region located around the display region and capable of surrounding the display region. A display unit 11 for realizing a display function may be prepared in advance on the display region of the base substrate 10.

A light conversion structure 2 capable of converting the received first light into the second light is prepared in the non-display region of the provided substrate 10, and the second light converted by the light conversion structure 2 has the effect of curing the organic material.

After the display unit 11 and the light conversion structure 2 are prepared on the base substrate 10, a composite packaging layer is prepared on the surface of the base substrate 10 in which the display unit 11 and the light conversion structure 2 are formed. The composite packaging layer may include one or more organic packaging layers 3 and one or more inorganic packaging layers 4 that are alternately stacked. The preparing the one or more organic packaging layers 3 may specifically include the following steps.

A rheological organic material capable of curing under the irradiation of the second light is prepared. The rheological organic material includes an organic matrix, a photoinitiator, a reactive diluent, and various other additives. The volume ratio of the organic matrix in the mixture is greater than 95%.

By using the inkjet printing technology, the prepared rheological organic material is printed on the surface of the base substrate 10 in which the display unit 11 and the light conversion structure 2 are formed. The specific position of printing may be selected as the surface of the display unit 11 away from the base substrate 10. After the rheological organic material is printed on the surface of the display unit 11, it will slowly level on the base substrate 10 to form a rheological organic material layer. Moreover, due to the effect of the liquid surface tension, the rheological organic material becomes thinner in the direction perpendicular to the base substrate 10 during its flowing to the non-display region of the base substrate 10. When the rheological organic material flows to the light conversion structure 2 located in the non-display region, the light conversion structure 2 is irradiated with the first light, so that the rheological organic material layer in a region in which the light conversion structure 2 is located is cured with the second light converted by the light conversion structure 2; and an orthogonal projection of the rheological organic material layer on the base substrate 10 is surrounded by an orthogonal projection of the light conversion structure 2 on the base substrate 10, to prevent the rheological organic material layer from continuing extending the edge of the base substrate 10.

After the rheological organic material levels, all the rheological organic material layer is cured to form the organic packaging layer 3. An orthogonal projection of the formed organic packaging layer 3 on the base substrate 10 is surrounded by an orthogonal projection of the light conversion structure 2 on the base substrate 10.

It should be noted that the thickness of the prepared organic packaging layer 3 may be 10 μm to 20 μm, but not limited thereto.

As can be seen from the above, the method for packaging the display substrate provided by the embodiments of the present disclosure can produce the following beneficial technical effects: by curing the rheological organic material layer in the region in which the light conversion structure 2 is located, the rheological organic material layer is confined within the region defined by the light conversion structure 2, to prevent the rheological organic material layer from extending toward the edge of the base substrate 10; thus, the inorganic packaging layer 4 can completely cover the organic packaging layer 3, thereby avoiding the organic packaging layer 3 to be exposed to water and oxygen in the air, and effectively improving the reliability of packaging the display substrate.

In an optional embodiment, the preparing the light conversion structure 2 in the non-display region of the base substrate 10 may specifically include: preparing at least two retaining wall patterns 21 in the non-display region of the base substrate, each of the at least two retaining wall patterns 21 surrounding the display region, heights of the at least two retaining wall patterns 21 in a direction perpendicular to the base substrate 10 gradually increase along a direction away from the display region, and a groove is formed between adjacent retaining wall patterns 21; and preparing a light conversion pattern 20 in the groove, the light conversion pattern 20 including a light conversion material capable of converting the received first light into the second light.

Specifically, taking each retaining wall pattern 21 made of photoresist resin as an example, the specific preparing the retaining wall pattern 21 includes: forming the photoresist resin film using photoresist resin; and patterning the formed photoresist resin film through conventional process such as exposure and development, to form each retaining wall pattern 21.

In the packaging method according to the above-mentioned embodiment, each retaining wall pattern 21 arranged at intervals and surrounding the display region of the base substrate 10 is formed, so that a groove surrounding the display region can be formed between adjacent retaining wall patterns 21. Then, in each groove, a light conversion pattern 20 capable of converting the received first light into the second light having a curing effect on the organic material is prepared. Therefore, in the process of preparing the organic packaging layers 3, when the rheological organic material flows to the region in which the groove is located in any direction, the second light converted by the light conversion pattern 20 in the groove can cure the rheological organic material layer in a region in which the groove is located, so that the rheological organic material can be restricted from flowing out of the light conversion structure 2 and continuing extending towards the edge of the base substrate 10 in all directions. This allows that an orthogonal projection of the organic packaging layer 3 on the base substrate 10 to be surrounded by an orthogonal projection of the light conversion structure 2 on the base substrate 10 when all the rheological organic material layers are cured to form the organic packaging layer 3.

In the packaging method according to the above embodiment, along a direction away from the display region, at least two retaining wall patterns 21 with heights gradually increases in a direction perpendicular to the base substrate 10 are formed, so that along a direction away from the display region, the blocking effect of the retaining wall pattern 21 on the rheological organic material layer gradually increases. This is more advantageous for forming the organic packaging layer 3 in a region defined by the light conversion structure 2 on the base substrate 10.

It should be noted that the height of the prepared retaining wall pattern 21 in the direction perpendicular to the base substrate 10 can be set according to actual needs. For example, when the first retaining wall pattern, the second retaining wall pattern, and the third retaining wall pattern that sequentially distributed along a direction away from the display region are prepared on the base substrate 10, the height of the first retaining wall pattern may be set to be 1 μm to 2 μm, the height of the second light retaining wall pattern may be set to be 3 μm to 4 μm, and the height of the third retaining wall pattern may be set to be 5 μm to 6 μm. In addition, the specific shape of the retaining wall pattern 21 can also be set according to actual needs. For example, the cross section of the retaining wall pattern 21 in the direction perpendicular to the base substrate 10 is square or trapezoidal. In addition, the interval between the adjacent retaining wall patterns 21 may be set to be 0.05 mm to 2 mm, but not limited thereto.

In an optional embodiment, the preparing the light conversion pattern 20 in the groove specifically includes: preparing a solution of the light conversion nanoparticles; and preparing the light conversion pattern 20 in the groove from the solution of the light conversion nanoparticles through inkjet printing technology.

Specifically, there are various ways to prepare the light conversion pattern 20. For example, a solution of light conversion nanoparticles may be prepared first, then the solution of light conversion nanoparticles is printed in a groove through inkjet printing technology, and then the solution of light conversion nanoparticles may be dried, to form the light conversion pattern 20.

In the packaging method according to the above embodiment, the light conversion pattern 20 is formed through inkjet printing technology, and the light conversion pattern 20 can be accurately formed in the groove, thereby making the process of preparing the light conversion pattern 20 more convenient and efficient.

Optionally, the preparing the solution of light conversion nanoparticles according to the above embodiment may specifically include mixing a compound doped with rare earth ions with a solvent, to prepare the solution of light conversion nanoparticles. The matrix compound includes one or more of oxides, fluorides, oxyfluorides, sulfides and halides. Specifically, the doped rare earth ions can be selected from lanthanum (La), cerium (Ce), praseodymium (Pr), neodymium (Nd), promethium (Pm), samarium (Sm), europium (Eu), gadolinium (Gd), Terbium (Tb), dysprosium (Dy), holmium (Ho), erbium (Er), thulium (Tm), ytterbium (Yb), lutetium (Lu), scandium (Sc), yttrium (Y) ions, etc. The selected solvent can be selected from methanol, ethanol and other solvents.

Optionally, a rare earth ion-doped compound and a solvent such as methanol or ethanol may be formulated into a solution with a volume ratio of 5% to 20%, and the inkjet printing is performed in the groove by inkjet printing, and then the solution of the light conversion nanoparticles formed in the groove is dried at a temperature of 50 □ to 80° C.

At present, the light conversion efficiency of the light conversion pattern 20 prepared from the light conversion nanoparticle solution can reach 62.5% or more.

Optionally, the forming the one or more organic packaging layers 3 may specifically include preparing the organic packaging layers 3 corresponding to the grooves respectively. Specifically, during the forming the rheological organic material layer corresponding to the organic packaging layer 3, the light conversion pattern in a target groove corresponding to the organic packaging layer 3 is irradiated with the first light, so that the rheological organic material layer in a region in which the target groove is located is cured with the second light converted from the first light by the light conversion pattern, and in a direction perpendicular to the base substrate 10, the rheological organic material layer in a region in which the target groove is located is lower than the retaining wall pattern 21 away from the display region among the retaining wall pattern 21 for forming the target groove.

When actually preparing the composite packaging layer, the specific layer numbers of the organic packaging layers 3 and the inorganic packaging layers 4 can be set according to actual needs. For example, a single organic packaging layer 3 or multiple organic packaging layers 3 may be prepared. In order to better prevent the rheological organic material from flowing out of the region defined by the light conversion structure 2 on the base substrate 10, when preparing the multiple organic packaging layers 3, each organic packaging layer 3 may be corresponding to one groove, that is, each organic packaging layer 3 corresponds to one light conversion pattern 20. In more detail, the first organic packaging layer to the Nth organic packaging layer that are sequentially stacked are prepared in a direction away from the base substrate 10, and along a direction away from the display region of the base substrate 10, the first groove to the Nth groove distributed in sequence are prepared, and a retaining wall pattern 21 is shared between adjacent grooves; and the first organic packaging layer corresponds to the first groove, and the second organic packaging layer corresponds to the second groove, and so on, the Nth organic packaging layer corresponds to the Nth groove.

In the preparing the organic packaging layers 3 and the grooves which correspond respectively with each other, when forming each rheological organic material layer corresponding to the organic packaging layer 3, the light conversion pattern in the target groove corresponding to the organic encapsulation layer 3 can be irradiated with the first light, so that the rheological organic material layer in a region in which the target groove is located is irradiated and cured with the second light converted from the first light by the light conversion pattern. This reduces the fluidity of the rheological organic material in the region in which the target groove is located, so that the rheological organic material layer in the region in which the target groove is located does not continue extending toward the edge of the base substrate 10, and in a direction perpendicular to the base substrate 10, the rheological organic material layer in a region in which the target groove is located is lower than the retaining wall pattern 21 away from the display region among the retaining wall pattern 21 for forming the target groove.

There are various ways to irradiate the light conversion pattern 20 located in the groove with the first light, and two specific irradiation manners are given below, but not limited thereto.

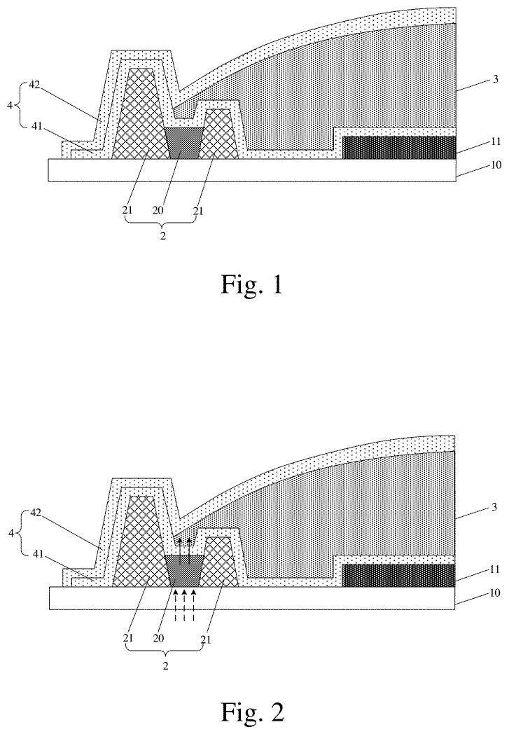

In the first manner, as shown in FIG. 2, when the base substrate 10 is a light transmitting substrate and the layers between the base substrate 10 and the light conversion structure 2 are all light transmitting film layers; and the irradiating the light conversion structure 2 with the first light specifically includes: irradiating the light conversion structure 2 with the first light (as shown by the dotted line with an arrow in FIG. 2) from the side of the base substrate 10, and after the light conversion structure 2 has converted the first light into the second light (as shown by the solid line with an arrow in FIG. 2), directly irradiating the rheological organic material layer in the region in which the light conversion structure 2 is located with the second light.

Specifically, when the base substrate 10 is a light transmitting substrate 10 and the film layers between the base substrate 10 and the light conversion structure 2 are both light transmitting film layers, the light conversion structure 2 can be directly irradiated with the first light from a side of the base substrate 10 (specifically, the light conversion pattern 20 in the light conversion structure 2 is irradiated). The first light may directly pass through the film layer between the base substrate 10 and the light conversion structure 2, to irradiate the light conversion structure 2. After the light conversion structure 2 has converted the received first light into the second light, the second light can directly irradiate the rheological organic material layer in the region in which the light conversion structure 2 is located, to cure the rheological organic material layer in the region in which the light conversion structure 2 is located.

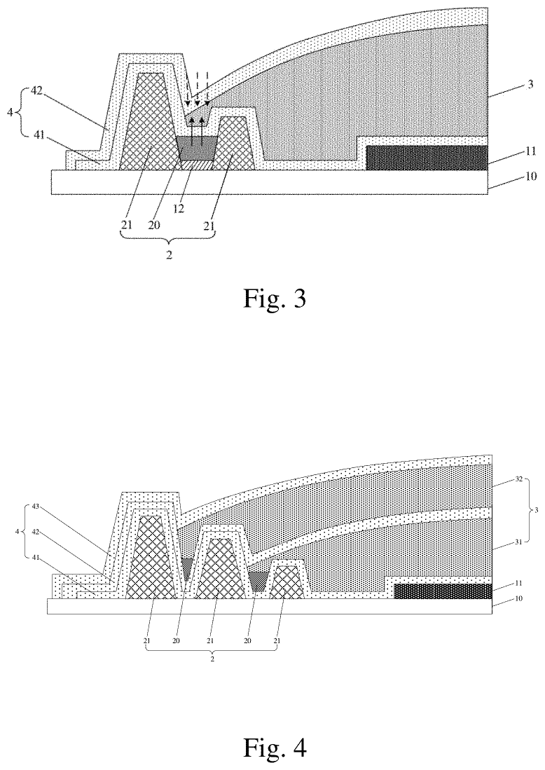

In the second manner, as shown in FIG. 3, when a reflective layer 12 with a reflective effect is arranged between the base substrate 10 and the light conversion structure 2, the irradiating the light conversion structure 2 with the first light specifically includes: irradiating the light conversion structure 2 with the first light (as shown by the dotted line with an arrow in FIG. 2) from side of the light conversion structure 2 away from the base substrate 10, and after the light conversion structure 2 has converted the first light into the second light (as shown by the solid line with an arrow in FIG. 2), reflecting the second light through the reflective film layer 12 having a reflective effect, to irradiate the rheological organic material layer in the region in which the light conversion structure 2 is located with the second light.

Specifically, when a reflective layer 12 having a reflective effect is arranged between the base substrate 10 and the light conversion structure 2, the light conversion structure 2 can be irradiated with the first light from a side of the light conversion structure 2 away from the base substrate 10 (specifically, the light conversion pattern 20 in the light conversion structure 2 is irradiated). Since the organic packaging layers 3 and the inorganic packaging layers 4 formed on the side of the light conversion structure 2 away from the base substrate 10 have good light transmittance, the first light is capable of passing through the organic packaging layers 3 and the inorganic packaging layers 4 to irradiate the light conversion structure 2. After the light conversion structure 2 has converted the received first light into the second light, the second light irradiates the reflective layer 12 having a reflective effect between the base substrate 10 and the light conversion structure 2, and under the reflection of the reflective layer 12, it irradiates the rheological organic material layer in the region in which the light conversion structure 2 is located, to cure the rheological organic material layer in the region in which the light conversion structure 2 is located.

When the light conversion structure 2 is irradiated with the first light, a short-distance concentrated irradiation method may be adopted. In this way, the first light can be accurately irradiated on the light conversion pattern 20, which not only has a low light source loss and a high light conversion efficiency of light conversion pattern 20, but also prevents the first light from irradiating the outside and reduces the possibility of light pollution.

In addition, when the light conversion structure 2 is irradiated with the first light, a manner for irradiating the entire display substrate may also be adopted. This method requires low equipment accuracy and can reduce equipment costs.

In an optional embodiment, the first light may be an infrared light or a visible light, and the second light may be an ultraviolet light. When the infrared light is selected as the first light, for example, the infrared light can be selected to be in a range of 800 nm to 1100 nm, the light intensity can be selected to be in a range of 100 J/cm² to 200 J/cm², and the wavelength of the converted ultraviolet light can be in a range of 100 nm to 420 nm.

Specifically, the principle that the light conversion pattern 20 has converted the first light into the second light is the principle of up-conversion luminescence principle. That is, under the excitation of long-wavelength light, light with a wavelength shorter than that of the excitation light can be continuously emitted. Up-conversion luminescence mainly includes three luminescence mechanisms: excited state absorption, energy transfer up-conversion and photon avalanche. These processes are achieved by the continuous absorption of one or more photons by the energy level of the active ions doped in the crystal particles. These activated ions generally have f electrons and d electrons, which are used for up-conversion luminescence due to having a large number of metastable energy levels.

Optionally, when the first light includes an infrared light and the second light includes an ultraviolet light, the preparing the at least two retaining wall patterns 21 in the non-display region of the base substrate 10 specifically includes: preparing an ultraviolet blocking material; depositing an ultraviolet blocking material to form a blocking film, and the blocking film at least covers the non-display region of the base substrate 10; and patterning the blocking thin film to obtain the at least two retaining wall patterns 21.

A variety of materials is used for preparing the retaining wall pattern 21. For example, the ultraviolet blocking material may be selected to prepare the retaining wall pattern 21. Specifically, the ultraviolet blocking material may be prepared first, and then the ultraviolet blocking material is deposited on the base substrate 10 to form a blocking thin film, and the blocking thin film may cover the entire region of the base substrate 10. Then, the formed blocking thin film is exposed by a mask, to form a blocking thin film reserved region and a blocking thin film removal region. The blocking thin film reserved region corresponds to the region in which the retaining wall pattern 21 is located, and the blocking thin film removal region corresponds to a region other than the region in which the retaining wall pattern 21 is located. Finally, the exposed blocking thin film is developed with a developing solution to remove the blocking thin film located in the blocking thin film removal region, to form at least two retaining wall patterns 21 located in the blocking thin film reserved region.

In addition to the effect of blocking the rheological organic material layer, the retaining wall pattern 21 prepared by the packaging method according to the above embodiment has the effect of blocking the ultraviolet light. The retaining wall pattern 21 having the effect of blocking the ultraviolet light is arranged, so that the ultraviolet lights converted by the light conversion pattern 20 can only irradiate the rheological organic material layer along the direction not blocked by the retaining wall pattern 21, and will not pass through the retaining wall pattern 21 to be irradiated into the rheological organic material layer located within the retaining wall pattern 21 (that is, the side of the retaining wall pattern 21 proximate to the display region). Therefore, in addition to confine the range of the rheological organic material layer, the retaining wall pattern 21 prepared by the packaging method according to the above embodiment is also capable of limiting the second light to only cure the rheological organic material layer flowing above the light conversion structure 2, to prevent the ultraviolet light converted by the light conversion pattern 20 from passing through the retaining wall pattern 21 and irradiating the rheological organic material layer located within the retaining wall pattern 21, so that the rheological organic material layer can evenly level, and thus the overall uniformity of the formed organic packaging layer 3 is ensured.

Optionally, among the prepared plurality of retaining wall patterns 21, the retaining wall pattern 21 furthest away from the display region may be prepared without using an ultraviolet blocking material.

Optionally, the preparing the ultraviolet blocking material specifically includes doping an infrared quantum dot material in the photoresist resin, to form an ultraviolet blocking material. Specifically, the infrared quantum dot material doped in the photoresist resin can be selected from one or more of cadmium selenide (CdSe), cadmium sulfide (CdS), cadmium telluride (CdTe), zinc selenide (ZnSe), and silver sulfide (AgS). The retaining wall pattern 21 made of the ultraviolet blocking material doped with the infrared quantum dot material can convert the received ultraviolet light into an infrared light and emit it. In more detail, after the ultraviolet light converted by the light conversion pattern 20 irradiates the retaining wall pattern 21 proximate to the display region, the retaining wall pattern 21 can convert the received ultraviolet light into an infrared light and then it irradiates the rheological organic material layer located within the retaining wall pattern 21, and the infrared light does not have a curing effect on the rheological organic material layer located with the retaining wall pattern 21. Therefore, this ensures that the rheological organic material layer can evenly level, and that the entire uniformity of the formed organic packaging layer 3 is ensured.

In an optional embodiment, the above preparing the one or more inorganic packaging layers 4 specifically includes: preparing a plurality of inorganic packaging layer 4, and an orthogonal projection of the light conversion structure 2 on the base substrate 10 is located within an orthogonal projection of the inorganic packaging layer 4 on the base substrate 10, the inorganic packaging layers 4 and the organic packaging layers 3 are alternately stacked, and the outermost layer on the outer surface of the composite packaging layer is the inorganic packaging layer 4.

Various materials can be used to prepare the inorganic packaging layer 4, as long as the prepared inorganic packaging layer 4 has a good effect of blocking water and oxygen, and the prepared inorganic packaging layer 4 has good light transmittance. For example, one or more of silicon nitride (SiNₓ), silicon dioxide (SiO₂), silicon carbide (SiC), aluminum oxide (Al₂O₃), zinc sulfide (ZnS), and zinc oxide (ZnO) may be used. The inorganic packaging layer 4 can be prepared by a conventional preparation method, for example, chemical vapor deposition (CVD), sputtering process, or atomic layer deposition (ALD). The thickness of the prepared inorganic packaging layer 4 can be set according to actual needs. For example, the thickness of the inorganic packaging layer 4 in the direction perpendicular to the base substrate 10 is in a range of 0.05 μm to 2.5 μm.

In order to more clearly explain the packaging method provided according to the above embodiment, two specific embodiments are given below.

### Embodiment 1

As shown in FIG. 1, the preparing two retaining wall patterns specifically includes: doping cadmium selenide (CdSe) and zinc sulfide (ZnS) quantum dots having a particle size of 5 nm to 15 nm and capable of absorbing ultraviolet light into the photoresist resin, to form an ultraviolet blocking material; preparing a first retaining wall pattern and a second retaining wall pattern from the ultraviolet blocking material in the non-display region of the base substrate 10, in which the first retaining wall pattern is located between the display region and the second retaining wall pattern, and a first groove is formed between the first retaining wall pattern and the second retaining wall pattern. The height of the first retaining wall pattern in the direction perpendicular to the base substrate 10 is about 2 μm, the height of the second retaining wall pattern in the direction perpendicular to the base substrate 10 is about 3 μm, and the interval between the first retaining wall pattern and the second retaining wall pattern is about 0.5 mm.

The preparing the light conversion pattern 20 in the groove specifically includes: preparing a methanol solution of β ution₄:Yb³⁺ and/or Tm³⁺/CdSe nanoparticles having 20% volume concentration; printing the solution into first groove confined by the first retaining wall pattern and the second retaining wall pattern through inkjet printing technology, and then drying the solution printed in the first groove at about 80° C., to prepare the first light conversion pattern in the first groove.

The preparing the composite packaging layer specifically includes: forming a SiNₓ thin film covering the first retaining wall pattern and the second retaining wall pattern and having a thickness of about 1 μm in a direction perpendicular to the base substrate 10 through a CVD method as the first inorganic packaging layer 41; on the side of the first inorganic packaging layer 41 away from the base substrate 10, printing the first rheological organic material within the range defined by the second retaining wall pattern through inkjet printing technology, to form a first rheological organic material layer, and irradiating the first light conversion pattern with the first light, so that the second light converted from the first light conversion pattern by the first light conversion pattern cures the first rheological organic material layer in the region in which the first groove is located, and in the direction perpendicular to the base substrate 10, the first rheological organic material layer in the region in which the first groove is located is lower than the second retaining wall pattern; after the first rheological organic material has levelled, all of the first rheological organic material layer is cured by being irradiated with an ultraviolet light, to form the first organic packaging layer 3, in which the maximum thickness of the first organic packaging layer 3 in the direction perpendicular to the base substrate 10 may be 10 μm; and on a side of the first organic packaging layer 3 away from the base substrate 10, preparing a second inorganic packaging layer 42 from Al₂O₃ material through ALD process, in which the maximum thickness of the second organic packaging layer 42 in the direction perpendicular to the base substrate 10 may be 0.05 μm.

After the above preparation steps, the packaging structure shown in FIG. 1 is prepared.

### Embodiment 2

As shown in FIG. 4, a packaging structure including three retaining wall patterns and two organic material layers are prepared. Except for the following differences, the preparation method of Example 2 is exactly the same as the preparation method of Example 1:

1. A third retaining wall pattern was also prepared on the periphery of the second retaining wall pattern in a similar manner, and the height of the third retaining wall pattern in the direction perpendicular to the base substrate 10 is 4 μm.

2. A second groove is formed between the second retaining wall pattern and the third retaining wall pattern in a similar manner, and a second light conversion pattern is prepared in the second groove in a similar manner.

3. A second organic packaging layer 32 and a third inorganic packaging layer 43 are additionally prepared in a manner similar to Example 1, in which the height of the second organic packaging layer 32 in a direction perpendicular to the base substrate 10 is 10 μm, and the height of the third inorganic packaging layer 43 in the direction perpendicular to the base substrate 10 is 1 μm.

4. Before the preparing the first light conversion pattern and the second light conversion pattern, the first inorganic packaging layer 41 is prepared.

For other specific preparation steps of Embodiment 2, please refer to the description of Embodiment 1, which will not be repeated here.

According to an embodiment of the present disclosure, the present disclosure also provides a packaging structure of a display substrate, including:

a base substrate 10, the base substrate 10 including a display region and a non-display region surrounding the display region;

a light conversion structure arranged in the non-display region 2, in which the light conversion structure 2 includes a light conversion material capable of converting the received first light into the second light having a curing effect on organic materials;

a composite packaging layer arranged on a surface of the base substrate 10 on which the light conversion structure 2 is formed, in which the composite packaging layer includes at least one organic packaging layer 3 and at least one inorganic packaging layer 4 that are alternately stacked, an orthogonal projection of the organic packaging layer 3 on the base substrate 10 partially overlaps an orthogonal projection of the light conversion structure 2 on the base substrate 10, and the orthogonal projection of the organic packaging layer 3 on the base substrate 10 is surrounded by the orthogonal projection of the light conversion structure 2 on the base substrate 10.

Optionally, the packaging structure is prepared by the packaging method according to the above embodiment.

The above substrate 10 may be a transparent substrate 10 or an opaque substrate. The base substrate 10 includes a display region and a non-display region located around the display region and capable of surrounding the display region. A display unit 11 for realizing a display function is arranged on the display region of the base substrate 10. A light conversion structure 2 capable of converting the received first light into the second light is arranged in the non-display region of the base substrate 10. The second light converted by the light conversion structure 2 has the effect of curing the organic material.

A composite packaging layer is arranged on the surface of the base substrate 10 on which the display unit 11 and the light conversion structure 2 are formed. The composite packaging layer may include an organic packaging layer 3 and an inorganic packaging layer 4 that are stacked. Optionally, the preparing the one or more organic packaging layers 3 specifically includes: preparing a rheological organic material capable of curing under the irradiation of the second light, in which the rheological organic material includes an organic matrix, a photoinitiator, an active diluent, and other auxiliary agents, and the volume ratio of the organic matrix in the mixture is greater than 95%; printing the prepared rheological organic material on a surface of the base substrate 10 in which the display unit 11 and the light conversion structure 2 are formed through inkjet printing technology, the specific printing position can be selected as the surface of the display unit 11 away from the base substrate 10, and after the rheological organic material is printed on the surface of the display unit 11, it will slowly level on the base substrate 10 to form a rheological organic material layer, moreover, due to the effect of liquid surface tension, the rheological organic material becomes thinner in the direction perpendicular to the base substrate 10 during its flow to the non-display region of the base substrate 10; when the rheological organic material flows to the light conversion structure 2 located in the non-display region, irradiating the light conversion structure 2 with the first light, so that the second light converted by the light conversion structure 2 irradiates the rheological organic material layer in the region in which the light conversion structure 2 is located, to cure the rheological organic material layer in the region in which the light conversion structure 2 is located, and the orthogonal projection of the rheological organic material layer on the base substrate 10 is surrounded by the orthogonal projection of the light conversion structure 2 on the base substrate 10, to prevent the rheological organic material layer from continuing extending to the edge of the base substrate 10; and after the rheological organic material layer has levelled, curing all of the rheological organic material layer to form the organic packaging layer 3, so that the orthogonal projection of the formed organic packaging layer 3 on the base substrate 10 is surrounded by the orthogonal projection of the light conversion structure 2 on the base substrate 10.

Since the packaging structure of the display substrate according to the embodiments of the present disclosure is prepared by the packaging method according to the above embodiments, like the packaging method, the packaging structure of the display substrate according to the embodiments of the present disclosure will also produce the following beneficial technical effects: by curing in advance the rheological organic material layer in the region in which the light conversion structure is located, the rheological organic material layer is confined within the region defined by the light conversion structure, to prevent the rheological organic material layer from extending toward the edge of the base substrate; thus the inorganic packaging layer can completely cover the organic packaging layer, thereby avoiding the organic packaging layer to be exposed to water and oxygen in the air, and effectively improving the reliability of packaging the display substrate.

In an optional embodiment, the light conversion structure 2 includes: at least two retaining wall patterns 21, in which each of the at least two retaining wall patterns 21 surround the display region, the height of the at least two retaining wall patterns 21 in a direction perpendicular to the base substrate 10 gradually increases along a direction away from the display region, and a groove is formed between adjacent retaining wall patterns 21; and a light conversion pattern 20 arranged in the groove, in which light conversion pattern 20 includes a light conversion material capable of converting the received first light into second light.

Taking each retaining wall pattern 21 made of photoresist resin as an example to illustrate the preparing the retaining wall pattern 21. The preparing the retaining wall pattern 21 specifically includes: forming a photoresist resin thin film using photoresist resin glue, and patterning the formed photoresist resin thin film through conventional process such as exposure and development. to form each retaining wall pattern 21.

In the packaging structure according to the above embodiment, each retaining wall pattern 21 arranged at intervals and surrounding the display region of the base substrate 10 makes it possible to form a groove surrounding the display region between adjacent retaining wall patterns 21. Then, in each groove, a light conversion pattern 20 capable of converting the received first light into the second light having a curing effect on the organic material is arranged. Therefore, in the process of preparing the one or more organic packaging layers 3, when the rheological organic material flows to the region in which the groove is located in any direction, the second light converted by the light conversion pattern 20 in the groove can cure the rheological organic material layer in a region in which the groove is located, so that the rheological organic material can be restricted from flowing out of the light conversion structure 2 and continuing extending towards the edge of the base substrate 10 in all directions. This allows that an orthogonal projection of the organic packaging layer 3 on the base substrate 10 to be surrounded by an orthogonal projection of the light conversion structure 2 on the base substrate 10 when all the rheological organic material layers are cured to form the organic packaging layer 3.

Optionally, in the above packaging structure, along a direction away from the display region, at least two retaining wall patterns 21 with heights gradually increases in a direction perpendicular to the base substrate 10 are arranged. Therefore, along a direction away from the display region, the blocking effect of the retaining wall pattern 21 on the rheological organic material layer gradually increases, which is more advantageous for forming the organic packaging layer 3 in a region defined by the light conversion structure 2 on the base substrate 10.

In an optional embodiment, the organic packaging layers 3 may correspond to the grooves respectively. In the direction perpendicular to the base substrate 10, the portion of each organic packaging layer 3 in the region in which the target groove is located is lower than the retaining wall pattern 21 away from the display region among the retaining wall pattern 21 for forming the target groove. The target grooves correspond to the organic packaging layers 3 respectively.

The specific layer number of the organic packaging layers 3 and the inorganic packaging layers 4 included in the composite packaging layer can be set according to actual needs. For example, a single organic packaging layer 3 or multiple organic packaging layers 3, e.g., two layers or three layers, may be arranged. In order to better prevent the rheological organic material from flowing out of the region defined by the light conversion structure 2 on the base substrate 10, when arranging the multiple organic packaging layers 3, each organic packaging layer 3 may be corresponding to one groove, that is, each organic packaging layer 3 corresponds to one light conversion pattern 20. In more detail, the first organic packaging layer to the Nth organic packaging layer that are sequentially stacked are arranged along a direction away from the base substrate 10, and the first groove to the Nth groove distributed in sequence are arranged along a direction away from the display region of the base substrate 10. A retaining wall pattern 21 is shared between adjacent grooves. The first organic packaging layer corresponds to the first groove, and the second organic packaging layer corresponds to the second groove, and so on, the Nth organic packaging layer corresponds to the Nth groove.

In preparing an organic packaging layer 3 and an groove which correspond to each other respectively, during the forming each rheological organic material layer corresponding to the organic packaging layer 3, the light conversion pattern in a target groove corresponding to the organic packaging layer 3 is irradiated with the first light, so that the rheological organic material layer in a region in which the target groove is located is irradiated and cured with the second light converted from the first light by the light conversion pattern. This reduces the fluidity of the rheological organic material in the region in which the target groove is located, so that the rheological organic material layer in the region in which the target groove is located does not continue extending toward the edge of the base substrate 10. Therefore, in a direction perpendicular to the base substrate 10, the rheological organic material layer in a region in which the target groove is located is lower than the retaining wall pattern 21 away from the display region among the retaining wall pattern 21 for forming the target groove.

Optionally, the above composite packaging layer includes a plurality of inorganic packaging layers 4. An orthogonal projection of the light conversion structure 2 on the base substrate 10 is located within an orthogonal projection of the inorganic packaging layer 4 on the base substrate 10. The inorganic packaging layers 4 and the organic packaging layers 3 are alternately stacked, and the outermost layer located on the outer surface of the composite packaging layer is the inorganic packaging layer 4.

Various materials can be selected for the inorganic packaging layer 4, as long as the prepared inorganic packaging layer 4 has a good effect of blocking water and oxygen, and the prepared inorganic packaging layer 4 has good light transmittance.

In an optional embodiment, the first light may include an infrared light, the second light may include an ultraviolet light, and the at least two retaining wall patterns 21 may be made of an ultraviolet blocking material.

When the infrared light is selected as the first light, the infrared light can be selected to be, for example, in a range of 800 nm to 1100 nm, the light intensity can be selected to be in a range of 100 J/cm² to 200 J/cm², and the wavelength of the converted ultraviolet light can be in a range of 100 nm to 420 nm.

Optionally, the above ultraviolet blocking material may include: an infrared quantum dot material doped with a photoresist resin.

A variety of materials can be selected for the retaining wall pattern 21, for example, the ultraviolet blocking material can be selected to prepare the retaining wall pattern 21. Specifically, the ultraviolet blocking material may be prepared first, and then the ultraviolet blocking material is deposited on the base substrate 10 to form a blocking thin film, and the blocking thin film may cover the entire region of the base substrate 10. Then, the formed blocking thin film is exposed by a mask, to form a blocking thin film reserved region and a blocking thin film removal region. The blocking thin film reserved region corresponds to the region in which the retaining wall pattern 21 is located, and the blocking thin film removal region corresponds to a region other than the region in which the retaining wall pattern 21 is located. Finally, the exposed blocking thin film is developed with a developing solution to remove the blocking thin film located in the blocking thin film removal region, to form at least two retaining wall patterns 21 located in the blocking thin film reserved region.

In addition to the effect of blocking the rheological organic material layer, the retaining wall pattern 21 prepared from the ultraviolet blocking material has the effect of blocking the ultraviolet light. The retaining wall pattern 21 having the effect of blocking the ultraviolet light is arranged, so that the ultraviolet lights converted by the light conversion pattern 20 can only irradiate the rheological organic material layer along the direction not blocked by the retaining wall pattern 21, and will not pass through the retaining wall pattern 21 to be irradiated into the rheological organic material layer located within the retaining wall pattern 21 (that is, the side of the retaining wall pattern 21 proximate to the display region). Therefore, in addition to confine the scope of the rheological organic material layer, preparing the retaining wall pattern 21 from the above-mentioned ultraviolet blocking material can also limit the retaining wall pattern 21 to only cure the rheological organic material layer flowing above the light conversion structure 2. That is, the retaining wall pattern 21 realizes that the ultraviolet light converted by the light conversion pattern 20 can only cure a small range of the rheological organic material layer at the edge, to prevent the ultraviolet light converted by the light conversion pattern 20 from passing through the retaining wall pattern 21 and irradiating the rheological organic material layer located within the retaining wall pattern 21, so that the rheological organic material layer can evenly level, and thus the overall uniformity of the formed organic packaging layer 3 is ensured.

Optionally, among the prepared plurality of retaining wall patterns 21, the retaining wall pattern 21 furthest away from the display region may be prepared without using an ultraviolet blocking material.

Optionally, the infrared quantum dot material doped in the photoresist resin can be selected from one or more of CdSe, CdS, CdTe, ZnSe, and AgS. The retaining wall pattern 21 made of the ultraviolet blocking material doped with the infrared quantum dot material can convert the received ultraviolet light into an infrared light and emit it. Specifically, after the ultraviolet light converted by the light conversion pattern 20 irradiates the retaining wall pattern 21 proximate to the display region, the retaining wall pattern 21 can convert the received ultraviolet light into an infrared light and then the infrared light irradiates the rheological organic material layer located within the retaining wall pattern 21, and the infrared light does not have a curing effect on the rheological organic material layer located with the retaining wall pattern 21, thereby ensuring that the rheological organic material layer can evenly level and ensuring the overall uniformity of the formed organic packaging layer 3.

In an optional embodiment, the above-mentioned light conversion pattern 20 is prepared from a compound doped with rare earth ions. Optionally, the compound may include one or more of oxides, fluorides, oxyfluorides, sulfides, and halides.

In order to more clearly explain the packaging structure of the display substrate of the above embodiment, two specific embodiments are given below for detailed description.

### Embodiment 3

As shown in FIG. 1, the at least two retaining wall patterns include a first retaining wall pattern and a second retaining wall pattern. The first retaining wall pattern is located between the display region and the second retaining wall pattern, and a first groove is formed between the first retaining wall pattern and the second retaining wall pattern.

The light conversion pattern 20 includes a first light conversion pattern arranged in the first groove.

The composite packaging layer includes: a first inorganic packaging layer 41 arranged on a surface of the first light conversion pattern away from the base substrate 10; a first organic packaging layer 31 arranged on a surface of the first inorganic packaging layer 41 away from the base substrate 10, in which a portion of each first organic packaging layer 31 in the region in which the first groove is located is lower than the second retaining wall pattern in a direction perpendicular to the base substrate 10; and a second inorganic packaging layer 42 arranged on a surface of the first organic packaging layer 31 away from the base substrate 10.

### Embodiment 4

As shown in FIG. 4, the at least two retaining wall patterns include: a first retaining wall pattern, a second retaining wall pattern, and a third retaining wall pattern that are sequentially distributed along a direction away from the display region. A first groove is formed between the first retaining wall pattern and the second retaining wall pattern, and a second groove is formed between the second retaining wall pattern and the third retaining wall pattern.

The light conversion pattern 20 includes a first light conversion pattern arranged in the first groove, and a second light conversion pattern arranged in the second groove.

The composite packaging layer includes: a first inorganic packaging layer 41 arranged between the light conversion pattern and the base substrate 10; a first organic packaging layer 31 arranged on a surface of the first inorganic packaging layer 41 away from the base substrate 10, in which a portion of each first organic packaging layer 31 in the region in which the first groove is located is lower than the second retaining wall pattern in a direction perpendicular to the base substrate 10; a second inorganic packaging layer 42 arranged on a surface of the first organic packaging layer 31 away from the base substrate 10, in which the second light conversion pattern is located on the surface of the second inorganic packaging layer 42 away from the base substrate 10; a second organic packaging layer 32 arranged on a surface of the second inorganic packaging layer 42 away from the base substrate 10, in which a portion of each second organic packaging layer 32 in the region in which the second groove is located is lower than the third retaining wall pattern in a direction perpendicular to the base substrate 10; and a third inorganic packaging layer 43 arranged on a surface of the second organic packaging layer 32 away from the base substrate.

Unless otherwise defined, technical terms or scientific terms used herein have the normal meaning commonly understood by one skilled in the art in the field of the present disclosure, the words “first”, “second”, and the like used herein does not denote any order, quantity, or importance, but rather merely serves to distinguish different components. The “including”, “comprising”, and the like used in the present disclosure means that the element or item appeared in front of the word encompasses the element or item and their equivalents listed after the word, and does exclude other elements or items. The word “connected” or “connecting” and the like are not limited to physical or mechanical connections, but may include electrical connections, whether direct or indirect. “On”, “under”, “left”, “right” and the like are only used to represent relative positional relationships, and when the absolute position of the described object is changed, the relative positional relationship may also be changed, accordingly. Moreover, it will be understood that when an element, such as a layer, film, region, or substrate, is referred to as being “on” or “under” another element, the element may be directly “on” or “under” another element, or there may be an intermediate element. In the above embodiments, the specific features, structures, materials or features may be combined in any suitable manner in any one or more embodiments or examples.

The above description is merely the specific embodiment of the present disclosure, but the scope of the present disclosure is not limited thereto. Moreover, any person skilled in the art would readily conceive of modifications or substitutions within the technical scope of the present disclosure, and these modifications or substitutions shall also fall within the protection scope of the present disclosure. Therefore, the protection scope of the present disclosure should be determined by the scope of the claims.

1. A method for packaging a display substrate, comprising:
providing a base substrate, the base substrate comprising a display region and a non-display region surrounding the display region;
preparing a light conversion structure in the non-display region of the base substrate, the light conversion structure comprising a light conversion material capable of converting received first light into second light; and
preparing one or more organic packaging layers and one or more inorganic packaging layers on a surface of the base substrate on which the light conversion structure is formed, to form a composite packaging layer in which the organic packaging layers and the inorganic packaging layers are alternately stacked;
wherein the preparing the one or more organic packaging layers comprises:
forming a rheological organic material layer, and irradiating the light conversion structure with the first light, so that the rheological organic material layer in a region in which the light conversion structure is located is cured with the second light converted from the first light by the light conversion structure; and
curing all of the rheological organic material layer to form the one or more organic packaging layers, wherein the light conversion structure is arranged on a surface of the corresponding organic packaging layer close to the base substrate.

2. The method of claim 1, wherein the preparing the light conversion structure in the non-display region of the base substrate comprises:
preparing at least two retaining wall patterns in the non-display region of the base substrate, wherein each of the at least two retaining wall patterns surrounds the display region, heights of the at least two retaining wall patterns in a direction perpendicular to the base substrate gradually increase along a direction away from the display region, and a groove is formed between adjacent retaining wall patterns; and
preparing a light conversion pattern in the groove, the light conversion pattern comprising a light conversion material capable of converting the received first light into the second light.

3. The method of claim 2, wherein the preparing the one or more organic packaging layers comprises preparing the organic packaging layers corresponding to the grooves respectively,
wherein during the forming the rheological organic material layer corresponding to the organic packaging layer, the light conversion pattern in a target groove corresponding to the organic packaging layer is irradiated with the first light, so that the rheological organic material layer in a region in which the target groove is located is cured with the second light converted from the first light by the light conversion pattern, and in a direction perpendicular to the base substrate, the rheological organic material layer in a region in which the target groove is located is lower than the retaining wall pattern away from the display region among the retaining wall patterns for forming the target groove.

4. The method of claim 3, wherein the preparing the one or more inorganic packaging layers comprises preparing a plurality of inorganic packaging layers,
wherein an orthogonal projection of the light conversion structure on the base substrate is located within an orthogonal projection of any one of the plurality of inorganic packaging layers on the base substrate, the inorganic packaging layers and the organic packaging layers are alternately stacked, and an outermost layer located on an outer surface of the composite packaging layer is the inorganic packaging layer.

5. The method of claim 4, wherein the method comprises:
preparing a first retaining wall pattern and a second retaining wall pattern in the non-display region of the base substrate, wherein the first retaining wall pattern is located between the display region and the second retaining wall pattern, and a first groove is formed between the first retaining wall pattern and the second retaining wall pattern;
preparing a first light conversion pattern in the first groove;
preparing a first inorganic packaging layer;
preparing a first organic packaging layer, which comprises forming a first rheological organic material layer on a surface of the first inorganic packaging layer away from the base substrate, irradiating the first light conversion pattern with the first light, so that the first rheological organic material layer in a region in which the first groove is located is cured with the second light converted from the first light by the first light conversion pattern, and in a direction perpendicular to the base substrate, the first rheological organic material layer in a region in which the first groove is located is lower than the second retaining wall pattern, and curing all of the first rheological organic material layer; and
preparing a second inorganic packaging layer on a surface of the first organic packaging layer away from the base substrate.

6. The method of claim 2, wherein the at least two retaining wall patterns comprise a first retaining wall pattern, a second retaining wall pattern, and a third retaining wall pattern; a first groove is formed between the first retaining wall pattern and the second retaining wall pattern, and a second groove is formed between the second retaining wall pattern and the third retaining wall pattern; and the composite packaging layer comprises two organic packaging layers and three inorganic packaging layers.

7. The method of claim 1, wherein the base substrate is a light transmitting substrate, and layers between the base substrate and the light conversion structure are all light transmitting layers.

8. The method of claim 7, wherein the irradiating the light conversion structure with the first light comprises irradiating the light conversion structure with the first light from a side of the base substrate, and after the light conversion structure has converted the first light into the second light, the second light directly irradiates the rheological organic material layer in a region in which the light conversion structure is located.

9. The method of claim 1, wherein a layer having light reflecting effect is arranged between the base substrate and the light conversion structure.

10. The method of claim 9, wherein the irradiating the light conversion structure with the first light comprises irradiating the light conversion structure with the first light from a side of the light conversion structure away from the base substrate, and after the light conversion structure has converted the first light into the second light, the second light is reflected by the layer having light reflecting effect, to irradiate the rheological organic material layer in a region in which the light conversion structure is located.

11. The method of claim 2, wherein the first light comprises an infrared light, and the second light comprises an ultraviolet light.

12. The method of claim 11, wherein the preparing the at least two retaining wall patterns in the non-display region of the base substrate comprises:
preparing an ultraviolet blocking material;
forming a blocking film by depositing the ultraviolet light blocking material, the blocking film at least covering the non-display region of the base substrate; and
patterning the blocking film to obtain the at least two retaining wall patterns.

13. A packaging structure for a display substrate, comprising:
a base substrate, the base substrate comprising a display region and a non-display region surrounding the display region;
a light conversion structure arranged in the non-display region, wherein the light conversion structure comprises a light conversion material capable of converting received first light into second light having a curing effect on organic materials;
a composite packaging layer arranged on a surface of the base substrate on which the light conversion structure is formed, wherein the composite packaging layer comprises one or more organic packaging layers and one or more inorganic packaging layers that are alternately stacked, an orthogonal projection of the organic packaging layer on the base substrate overlaps an orthogonal projection of the light conversion structure on the base substrate, and the light conversion structure is arranged on a surface of the corresponding organic packaging layer close to the base substrate.

14. The packaging structure of claim 13, wherein the light conversion structure comprises:
at least two retaining wall patterns, wherein each of the at least two retaining wall patterns surrounds the display region, heights of the at least two retaining wall patterns in a direction perpendicular to the base substrate gradually increase along a direction away from the display region, and a groove is formed between adjacent retaining wall patterns; and
a light conversion pattern arranged in the groove, the light conversion pattern comprising a light conversion material capable of converting the received first light into the second light.

15. The packaging structure of claim 14, wherein the organic packaging layers correspond to the grooves respectively, and in a direction perpendicular to the base substrate, a portion of each organic packaging layer in a region in which a target groove is located is lower than the retaining wall pattern away from the display region among the retaining wall pattern for forming the target groove, and the target grooves correspond to the organic packaging layers respectively.

16. The packaging structure of claim 15, wherein the composite packaging layer comprises a plurality of inorganic packaging layers, an orthogonal projection of the light conversion structure on the base substrate is located within an orthogonal projection of the plurality of inorganic packaging layers on the base substrate, the inorganic packaging layers and the organic packaging layers are alternately stacked, and an outermost layer located on an outer surface of the composite packaging layer is the inorganic packaging layer.

17. The packaging structure of claim 16, wherein the at least two retaining wall patterns comprise a first retaining wall pattern and a second retaining wall pattern, the first retaining wall pattern is located between the display region and the second retaining wall pattern, and a first groove is formed between the first retaining wall pattern and the second retaining wall pattern;
the light conversion pattern comprises a first light conversion pattern arranged in the first groove;
and the composite packaging layer comprises:
a first inorganic packaging layer arranged on a surface of the first light conversion pattern away from the base substrate;
a first organic packaging layer arranged on a surface of the first inorganic packaging layer away from the base substrate, wherein in a direction perpendicular to the base substrate, a portion of the first organic packaging layer in a region where the first groove is located is lower than the second retaining wall pattern; and
a second inorganic packaging layer arranged on a surface of the first organic packaging layer away from the base substrate,
wherein the first light conversion pattern is arranged between the first inorganic packaging layer and the base substrate or between the first inorganic packaging layer and the first organic packaging layer.

18. The packaging structure of claim 14, wherein the first light comprises infrared light, the second light comprises ultraviolet light, and the at least two retaining wall patterns are made of an ultraviolet blocking material.

19. The package structure of claim 18, wherein the light conversion pattern comprises a compound material doped with rare earth ions, and the compound material comprises one or more of oxides, fluorides, oxyfluorides, sulfides and halides.

20. The package structure of claim 18, wherein the at least two retaining wall patterns comprise a first retaining wall pattern, a second retaining wall pattern, and a third retaining wall pattern; a first groove is formed between the first retaining wall pattern and the second retaining wall pattern, and a second groove is formed between the second retaining wall pattern and the third retaining wall pattern; and the composite packaging layer comprises two organic packaging layers and three inorganic packaging layers.
